(19) United States
(12) Patent Application Publication
(10) Pub. No.: US 2005/0164499 A1
(43) Pub. Date: Jul. 28, 2005

(54) Electroless plating method and apparatus

(75) Inventors: Yoshinori Marumo, Nirasaki-shi (JP); Hiroshi Sato, Nirasaki-shi (JP); Miho Jomen, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/082,807

(22) Filed: Mar. 18, 2005

Related U.S. Application Data
(63) Continuation-in-part of application No. PCT/JP03/06499, filed on May 23, 2003.

(30) Foreign Application Priority Data
Sep. 27, 2002 (JP) 2002-283297

(51) Int. Cl. H01L 21/44; H01L 21/4763

(52) U.S. Cl. 438/678; 438/629; 438/622; 438/674; 438/614

(57) ABSTRACT

In a method of electroless plating, catalytically active nuclei are formed on a diffusion inhibiting layer (such as a barrier layer), the catalytically active nuclei being catalytically active on a reducing agent contained in an electroless plating solution, and an electroless plating is then carried out by using the electroless plating solution. The method allows the formation of an electrolessly plated coating on a barrier layer through the acceleration of the reaction of a reducing agent contained in an electroless plating solution by catalytically active nucleus.

This application is a Continuation-In-Part of PCT International Application No. PCT/JP03/06499 filed on May 23, 2003, which designated the United States.

### FIELD OF THE INVENTION

The present invention relates to an electroless plating method and apparatus for forming an electrolessly plated coating.

### BACKGROUND OF THE INVENTION

In a fabrication of a semiconductor device, there is performed a formation of a wiring on a semiconductor substrate.

Along with a recent trend of high integration of semiconductor devices, miniaturization of the wiring has been progressed and fabrication technique thereof has been accordingly developed. For example, as a method for forming a copper wiring, there has been utilized a dual damascene method wherein a copper seed layer is formed by a sputtering and a groove is buried by an electroplating to form a wiring and an interlayer connection. In this method, it is difficult to perform the electroplating on a surface where the seed layer is not formed.

Meanwhile, as a plating method wherein the seed layer is not required, there is an electroless plating method. In the electroless plating method for forming a coating by a chemical reduction, the formed coating acts as a self-catalyst, so that the coating made of a wiring material can be formed continuously. In accordance with the electroless plating, it is unnecessary to form the seed layer in advance, and there is a reduced concern that the coating becomes non-uniformed due to non-uniformity of the seed layer (particularly, step coverage in recess and protrusion portions).

For preventing a diffusion of the wiring material, there may be formed a coating on a barrier layer formed on a substrate. As for the barrier layer, there may be employed metal nitride such as TiN, TaN or the like. Since the metal nitride is nonreactive with the electroless plating, it is difficult to perform the electroless plating on the barrier layer.

There has been disclosed a technology capable of forming an electrolessly plated coating on the barrier layer by forming a copper in advance on the barrier layer through the sputtering or the like, in case of using the barrier layer (see Japanese Patent Laid-open Application No. 2001-85434).

However, in the above-disclosed technology, since the same material as the coating is formed on the barrier layer, the kind of processing is limited.

### SUMMARY OF THE INVENTION

It is, therefore, an object of the present invention to provide an electroless plating method and apparatus capable of forming an electrolessly plated coating on a barrier layer by various processes.

In accordance with one aspect of the present invention, there is provided an electroless plating method, including: a diffusion inhibition layer formation step for forming on a substrate a diffusion inhibition layer for inhibiting a diffusion of a specific material; a catalytically active nuclei formation step for forming catalytically active nuclei on at least a part of the diffusion inhibition layer formed on the substrate at the diffusion inhibition layer formation step, wherein the catalytically active nuclei are catalytically active on an oxidation reaction of a reducing agent in an electroless plating reaction and are made of a different catalytically active material from the specific material; and a coating formation step for forming a coating made of the specific material on the substrate, on which the catalytically active nuclei have been formed at the catalytically active nuclei formation step, by using an electroless plating solution containing the reducing agent.

After forming on a diffusion inhibition layer (e.g., a barrier layer) catalytically active nuclei made of a catalytically active material that has a catalytic activity for an oxidation reaction of a specific reducing agent contained in a plating solution, an electroless plating is performed by using an electroless plating solution.

Here, the catalytically active nuclei may be discontinuously formed on the diffusion inhibition layer. Namely, The catalytically active nuclei may be of a layer shaped continuous film, or a discontinuous film comprised of islands dispersed.

In accordance with another aspect of the present invention, there is provided an electroless plating method, including: a diffusion inhibition layer formation step for forming a diffusion inhibition layer for inhibiting a diffusion of a specific material on a substrate by a sputtering or a vacuum deposition, the diffusion inhibition layer being made of a non-catalytically active material that is not catalytically active for an oxidation reaction of a specific reducing agent and a catalytically active material that is catalytically active for an oxidation reaction of the specific reducing agent; and a coating formation step of forming a coating made of the specific material on the substrate, on which the diffusion inhibition layer has been formed at the diffusion inhibition layer formation step, by using an electroless plating solution containing the specific reducing agent.

After forming a diffusion inhibition layer (e.g., a barrier layer) containing a catalytically active material, an electroless plating is performed by using an electroless plating solution. A reaction of the reducing agent contained in an electrolessly plated coating is accelerated by the catalytically active material of the diffusion inhibition layer, so that the formation of the electrolessly plated coating may be carried out.

In accordance with still another aspect of the present invention, there is provided an electroless plating method, including: a diffusion inhibition layer formation step for forming a diffusion inhibition layer for inhibiting a diffusion of a specific material on a substrate by a sputtering or a vacuum evaporation, the diffusion inhibition layer being made of a catalytically active material that is catalytically active for an oxidation reaction of a specific reducing agent; and a coating formation step of forming a coating made of the specific material on the substrate, on which the diffusion inhibition layer has been formed at the diffusion inhibition layer formation step, by using an electroless plating solution containing the specific reducing agent.

After forming a diffusion inhibition layer (e.g., a barrier layer) by using a material that has a catalytic activity and a diffusion inhibiting property, an electroless plating is performed by using an electroless plating solution. A reaction of the reducing agent contained in an electrolessly plated coating is facilitated, so that the formation of the electrolessly plated coating may be performed.

In accordance with still another aspect of the present invention, there is provided an electroless plating apparatus including: a coating formation unit for forming a coating made of a specific material on a substrate on which a diffusion inhibition layer is formed by a sputtering or a vacuum deposition by using an electroless plating solution containing a specific reducing agent, the diffusion inhibition layer being made of a non-catalytically active material that is not catalytically active for an oxidation reaction of the specific reducing agent and a catalytically active material that is catalytically active for an oxidation reaction of the specified reducing agent, for inhibiting a diffusion of the specific material.

In accordance with still another aspect of the present invention, there is provided an electroless plating apparatus including: a coating formation unit for forming a coating made of a specific material on a substrate, on which a diffusion inhibition layer is formed by a sputtering or a vacuum deposition by using an electroless plating solution containing a specific reducing agent, the diffusion inhibition layer being made of a catalytically active material that is catalytically active for an oxidation reaction of the specific reducing agent, for inhibiting a diffusion of the specific material.

### BRIEF DESCRIPTION OF THE DRAWINGS

The above and other objects and features of the present invention will become apparent from the following description of preferred embodiments given in conjunction with the accompanying drawings, in which:

FIG. 1 provides a flowchart for showing a sequence of an electroless plating method in accordance with a first embodiment;

FIGS. 2A to 2D present cross sectional views of the wafer W for respective steps of FIG. 1;

FIG. 3 is a partial cross sectional view for showing an electroless plating apparatus used for the electroless plating of FIG. 1;

FIG. 4 offers a partial cross sectional view showing a state where the wafer W and the like installed in the electroless plating apparatus of FIG. 3 are tilted;

FIG. 5 is a flowchart for showing an exemplary sequence in case of performing the electroless plating by using the electroless plating apparatus in accordance with the first embodiment;

FIG. 6 is a partial cross sectional view for showing a status of the electroless plating apparatus in case of performing the electroless plating by following the sequence described in FIG. 5;

FIG. 7 is a partial cross sectional view for showing a status of the electroless plating apparatus in case of performing the electroless plating by following the sequence shown in FIG. 5;

FIG. 8 is a partial cross sectional view for showing a status of the electroless plating apparatus in case of performing the electroless plating by following the sequence described in FIG. 5;

FIG. 9 is a partial cross sectional view for showing a status of the electroless plating apparatus in case of performing the electroless plating by following the sequence described in FIG. 5;

FIG. 10 is a partial cross sectional view for showing a status of the electroless plating apparatus in case of performing the electroless plating by following the sequence described in FIG. 5;

FIG. 11 is a partial cross sectional view for showing a status of the electroless plating apparatus in case of performing the electroless plating by following the sequence described in FIG. 5;

FIG. 12 is a partial cross sectional view for showing performing the electroless plating by following the sequence described in FIG. 5;

FIG. 13 offers a flowchart for showing a sequence of an electroless plating method in accordance with a second embodiment;

FIGS. 14A and 14B provide cross sectional views of the wafer W for respective steps of FIG. 13;

FIG. 15 sets forth a flowchart for showing a sequence of an electroless plating method in accordance with a third embodiment; and

FIGS. 16A and 16B present cross sectional views of the wafer W for respective steps of FIG. 15.

### DETAILED DESCRIPTION OF THE PREFERRED EMBODIMENTS

Hereinafter, preferred embodiments of the present invention will be described in detail with reference to the accompanying drawings.

### First Embodiment

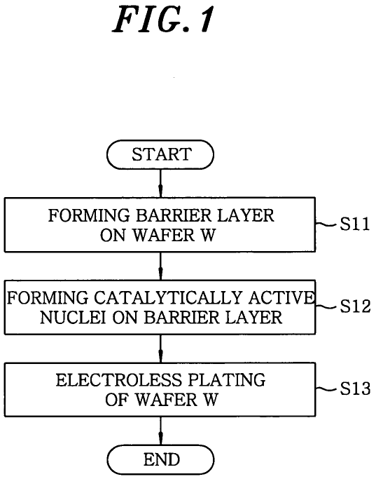

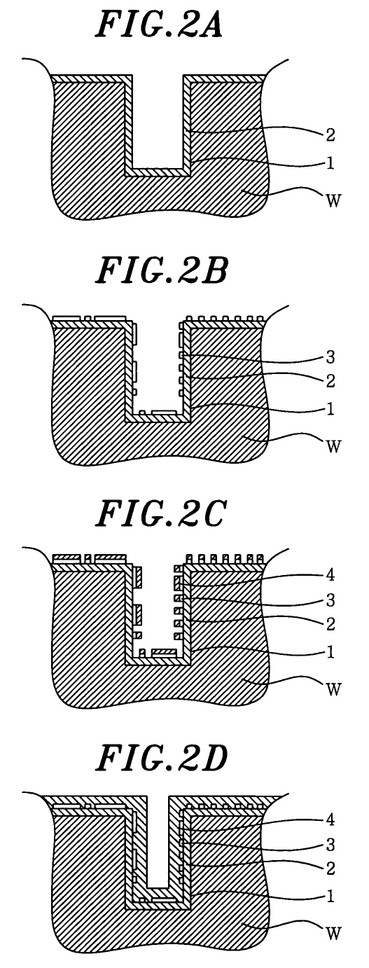

FIG. 1 is a flowchart for showing a sequence of an electroless plating method in accordance with the first embodiment. Further, FIGS. 2A to 2D present cross sectional views of the wafer W for respective steps of FIG. 1.

As shown in FIG. 1, in the electroless plating method in accordance with the first embodiment of the present invention, the wafer W is processed in the order of steps S11˜S13. Hereinafter, the processing sequence will now be explained in detail.

(1) Forming a Barrier Layer on a Wafer W (step S11, FIG. 2A)

A barrier layer is formed on the wafer W. The barrier layer functions as a diffusion inhibiting layer, and is to prevent a diffusion of a wiring material (e.g., copper) or the like. By the barrier layer, the wafer W is prevented from being contaminated due to the diffusion (e.g., electromigration) of the wiring material. As for the material of the barrier layer, there may be used, e.g., Ta, TaN, W, WN, Ti or TiN.

In the wafer W, there is formed an irregularity such as trench, via or the like for burying thereinto the wiring material; and the barrier layer is formed in correspondence with the irregularity. FIG. 2A shows a state where a barrier layer 2 is formed in correspondence with a recess 1. Further, the barrier layer 2 is formed by, e.g., a physical film deposition (sputtering, vacuum deposition or the like) or a chemical film deposition (CVD or the like).

(2) Forming Catalytically Active Nuclei on the Barrier Layer (step S12, FIG. 2B)

Catalytically active nuclei 3 are formed on the barrier layer 2. The catalytically active nuclei 3 are made of a catalytically active material that has a catalytic activity for facilitating an oxidation reaction of an electroless plating solution, particularly a reducing agent component thereof, to be used at step S13, and function as nuclei (origins) for forming an electrolessly plated coating. The catalytically active nuclei 3 may be of a layer shaped continuous film, or a discontinuous film comprised of islands dispersed.

Now, there will be shown an example of the catalytically active material for forming the catalytically active nuclei 3. The catalytically active material may be selected based on a reducing agent to be used as a component of an electroless plating solution explained hereinafter.

1) A case where the reducing agent is formaldehyde: Ir, Pd, Ag, Ru, Rh, Au or Pt.

A reaction during the electroless plating:
2HC(OH)O⁻+2OH⁻→2HCOO⁺+2H₂O+H₂↑+2e⁻

2) A case where the reducing agent is Hypophosphite: Au, Ni, Pd, Ag, Co or Pt (arranged in order of a catalytic activity from right to left (Au>Pt)).

A reaction during the electroless plating:
H₂PO₂⁻+2OH⁻→2H₂PO₃⁻+H₂↑+2e⁻

3) A case where the reducing agent is glyoxylic acid: Ir, Pd, Ag, Ru, Rh, Au or Pt.

A reaction during the electroless plating:
2HC(OH)O⁻+2OH⁻→2HCOO⁺+2H₂O+H₂↑+2e⁻

4) A case where the reducing agent is metal salt (cobalt nitrate, etc.): Ag, Pt, Rh, Ir, Pd or Au.

5) A case where the reducing agent is dimethylamine borane: Ni, Pd, Ag, Au or Pt.

A reaction during the electroless plating:
(CH₃)2HN.BH₃₊₃H₂O→H₃BO₃+(CH₃)₂H₂N⁺+5H⁺+6e⁻

(3) Electroless Plating on the Wafer W (step S13, FIGS. 2C and 2D)

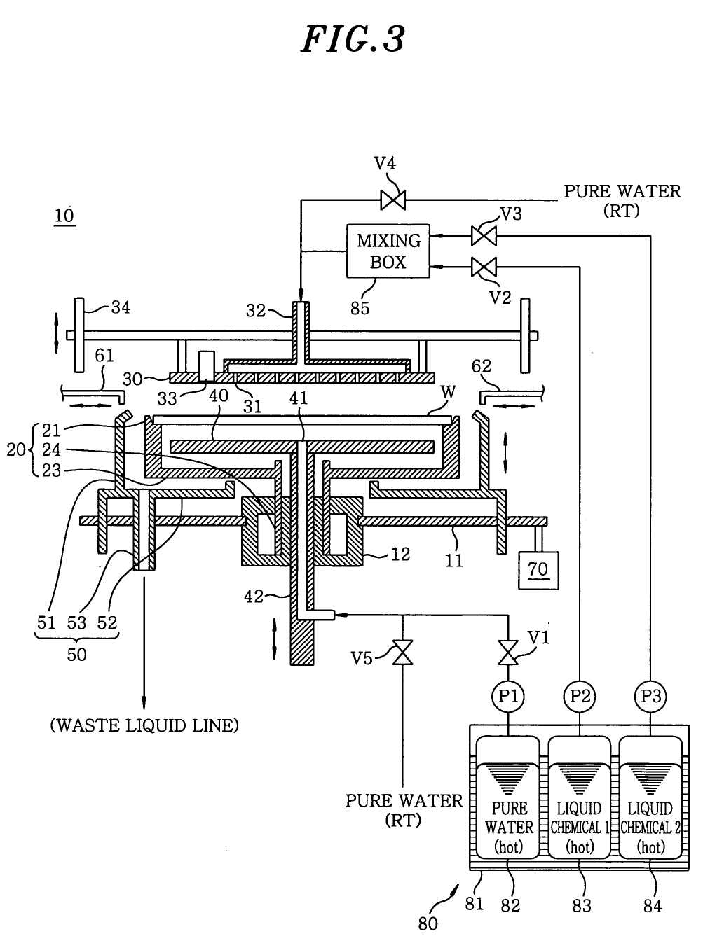

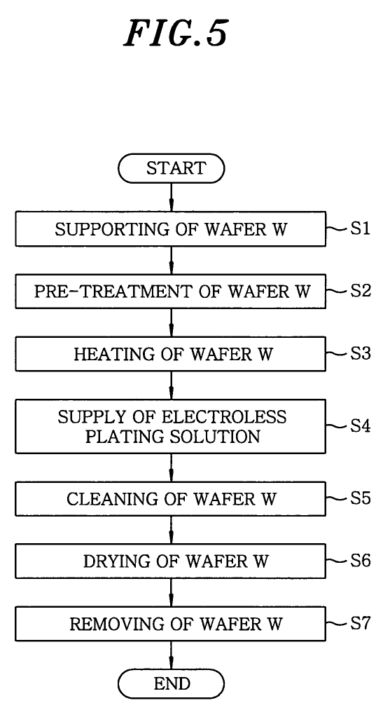

An electrolessly plated coating is formed by performing the electroless plating on the wafer W. As described below, the electroless plating may be performed by using the apparatus described in FIG. 3 in the sequence of FIG. 5.

At the initial stage of the electroless plating, the electrolessly plated coating is formed on the catalytically active nuclei 3 (FIG. 2C). Namely, in this stage, in case the catalytically active nuclei 3 are of a discontinuous film, the electrolessly plated coating becomes a discontinuous film, as well.

After that, the electrolessly plated coatings 4 on the catalytically active nuclei 3 are grown to spread over the surface of the wafer W. Namely, even though the catalytically active nuclei 3 are of a discontinuous film, the electrolessly plated coatings 4 on the catalytically active nuclei 3 are connected to each other to thereby form a continuous film.

Further, in case where the catalytically active nuclei 3 are of a continuous film, the processes for forming the electrolessly plated coatings 4 of the discontinuous films as described in FIGS. 2C and 2D are not necessarily needed to form a continuous electrolessly plated coating 4.

(Details of the Electroless Plating Apparatus Used for the Electroless Plating)

FIG. 3 is a partial cross sectional view for showing a configuration of an electroless plating apparatus 10 to be used for the electroless plating at step S13.

In the electroless plating apparatus 10, an electroless plating processing, a pre-treatment thereof, a cleaning processing and a dry processing after the plating processing can be performed on the wafer W of a substrate by using processing solutions.

As for the processing solutions, various liquids such as liquid chemicals for the pre-treatment and the post-treatment of the plating, pure water and the like, as well as the liquid chemical for the electroless plating can be employed.

As for the liquid chemical for use in the electroless plating (electroless plating solution), the following materials may be used by being mixed with each other and resolved in the pure water.

1) Metal salt: It is a material for providing metal ions forming a coating. In case of a copper coating, metal salt is, e.g., copper sulfate, copper nitrate, or copper chloride.

2) Complexing agent: It is a material to convert a metal into a complex such that metal ions are not deposited as hydrides under strong alkaline condition to thereby improve stability of the metal in a solution. As for the complexing agent, there may be used, e.g., HEDTA, EDTA, and ED as an amine based material; and citric acid, tartaric acid and glyoxylic acid as an organic material.

3) Reducing agent: It is a material for catalytically reducing and depositing metal ions. As for the reducing agent, there may be used, e.g., formaldehyde, hypophosphite, glyoxylic acid, metal salt (cobalt (II) nitrate, etc.), dimethylamine borane, stannic chloride or boron hydride compound.

4) Stabilizer: It is a material for preventing a plating solution from being naturally decomposed due to non-uniformity of oxide (cupric oxide in case of a copper coating). As for the stabilizer, there may used as nitrogen based material, e.g., bipyridyl, cyanide compound, thiourea, O-Phenanthroline, or neocuproine. Herein, bipyridyl preferentially forms a complex with, e.g., monovalent copper.

5) pH buffer: It is a material for suppressing variation in pH while a reaction of a plating solution progresses. As for the pH buffer, there may be used, e.g., boric acid, carbonic acid or oxycarboxylic acid.

6) Additive: It is a material for facilitating or suppressing deposition of a coating, or performing a modification on a surface or a coating.
As a material for suppressing the deposition rate of the coating, stabilizing a plating solution and improving the characteristic of the coating, there may be used, e.g., thiosulfuric acid or 2-MBT.
As a material for lowering surface tension of a plating solution to make the plating solution be placed uniformly on a surface of a wafer W, there may be used, e.g., polyalkylene glycol or polyethylene glycol as a nonionic surfactant material.

As shown in FIG. 3, the electroless plating apparatus 10 includes a base 11, a hollow motor 12, a wafer chuck 20 of a substrate supporting unit, an upper plate 30, a lower plate 40, a cup 50, nozzle arms 61 and 62, a substrate inclining mechanism 70 for regulating a tilt of a substrate and a solution supply unit 80. Here, the hollow motor 12, the wafer chuck 20, the upper plate 30, the lower plate 40, the cup 50 and the nozzle arms 61 and 62 are directly or indirectly connected to the base 11, so that they are moved with the base 11 tilted by the substrate inclining mechanism 70.

The wafer W is maintained and fixed by the wafer chuck 20, which is formed of plural wafer supporting claws 21, a wafer chuck bottom plate 23 and a wafer chuck supporting portion 24.

The plural wafer supporting claws 21 are disposed on an outer periphery of the wafer chuck bottom plate 23 to maintain and fix the wafer W.

The wafer chuck bottom plate 23 connected to the upper surface of the wafer chuck supporting portion 24 is of a substantially circular flat plate, and disposed on the bottom surface of the cup 50.

The wafer chuck supporting portion 24 of a substantially cylindrical shape is fitted in a circular opening formed in the wafer chuck bottom plate 23, and configured as a rotation axis of the hollow motor 12. As a result, it is possible to rotate the wafer chuck 20 by operating the hollow motor 12 while maintaining the wafer W. Further, since the cup 50 can be vertically moved as described below, the wafer chuck 20 disposed at the bottom of the cup 50 can accordingly vertically moved.

The upper plate 30 of a substantially circular flat plate has a heater (not shown), one or more processing solution injection openings 31, a processing solution introduction port 32 and a temperature measuring mechanism 33, and is connected to an elevating mechanism 34.

The heater is a heating unit, such as a heating wire or the like, for heating the upper plate 30. The caloric power of the heater is controlled by a controller (not shown), based on a temperature measurement result of the temperature measuring mechanism 33, such that the upper plate 30, and further, the wafer W are maintained at desired temperatures (e.g., in the range from room temperature to about 60° C.), respectively.

The one or more processing solution injection openings 31 are formed at a lower surface of the upper plate 30, through which the processing solution introduced from the processing solution introduction port 32 is to be discharged.

The processing solution introduction port 32 is placed at an upper side of the upper plate 30; and the processing solution introduced thereinto is discharged through the processing solution injection openings 31. As for the processing solution to be introduced into the processing solution introduction port 32, there may be alternately used pure water (RT: room temperature), and heated liquid chemicals 1 and 2 (e.g., in the range from room temperature to about 60° C.). Further, liquid chemicals 1 and 2 mixed in a mixing box 85 to be explained hereinafter (multiple liquid chemicals containing other liquid chemicals may be mixed, if necessary) may be introduced into the processing solution introduction port 32.

The temperature measuring mechanism 33 is a temperature measurement unit such as a thermocouple or the like, buried into the upper plate 30, for measuring a temperature of the upper plate 30.

The elevating mechanism 34, connected to the upper plate 30, vertically moves the upper plate 30 while allowing it to face the wafer W, so that the gap between the upper plate 30 and the wafer W can be controlled at, e.g., about 0.1˜500 mm. During the electroless plating, by allowing the wafer W to be disposed close to the upper plate 30 (such that, e.g., the gap between the wafer W and the upper plate 30 becomes 2 mm or less), the size of the gap is limited, so that the processing solution is uniformly supplied onto the surface of the wafer W and the amount of consumption thereof is reduced.

The lower plate 40 disposed to face the bottom surface of the wafer W is of a substantially circular flat plate type; and supplies heated pure water to the bottom surface of the wafer W to properly heat the wafer W while it being disposed close to the wafer W.

For efficiently heating the wafer W, it is preferable that the size of the lower plate 40 is approximately similar to that of the wafer W. Specifically, it is preferable that the size of the lower plate 40 is greater than 80% or 90% of an area of the wafer W.

The lower plate 40, having a processing solution injection opening 41 at the center of the upper surface thereof, is supported by a supporting portion 42.

The processing solution passing through the supporting portion 42 is discharged through the processing solution injection opening 41. As for the processing solution, there may be used pure water (RT: room temperature) or heated pure water (e.g., in the range from the room temperature to about 60° C.).

The supporting portion 42 penetrating through the hollow motor 12 is connected to an elevating mechanism (not shown) as a gap adjusting unit. By the operation of the elevating mechanism, the supporting portion 42, and further, the lower plate 40 can be vertically moved.

The cup 50, which accommodates therein the wafer chuck 20 and discharges therefrom the processing solution used for the processing of the wafer W, has a cup side portion 51, a cup bottom plate 52 and a waste liquid line 53.

The cup side portion 51 is of a substantially cylindrical shape, wherein the inner periphery thereof is formed along the outer periphery of the wafer chuck 20 and the top portion thereof is disposed in the vicinity of the upper portion of the supporting surface of the wafer chuck 20.

The cup bottom plate 52 connected to the lower portion of the cup side portion 51 has an opening at a position corresponding to the hollow motor 12; and the wafer chuck 20 is disposed at a position corresponding to the opening.

The waste liquid line 53 connected to the cup bottom plate 52 is to discharge from the cup 50 the waste liquid (the processing solution used for the processing of the wafer W) into a waste line or the like of the factory, in which the electroless plating apparatus 10 is installed.

The cup 50 connected to the elevating mechanism (not shown) can be vertically moved with respect to the base 11 and the wafer W.

The nozzle arms 61 and 62 are disposed in the vicinity of the top surface of the wafer W; and fluids such as the processing solution and air are discharged through openings of tip ends thereof. The fluid to be discharged may be properly selected from pure water, liquid chemical and nitrogen gas. To the nozzle arms 61 and 62, there are connected transfer mechanisms (not shown) for moving the nozzle arms 61 and 62 in a direction towards the center of the wafer W, respectively. In case where the fluids are discharged onto the wafer W, the nozzle arms 61 and 62 are moved to positions above the wafer. If the discharge is completed, the nozzle arms 61 and 62 are moved away outside the outer periphery of the wafer W. Further, the number of nozzle arms may be one or 3 or more, depending on the amount of the liquid chemical to be discharged or the kind thereof.

One end of the base 11 can be moved upward or downward by the substrate inclining mechanism 70 connected to the base 11, thereby tilting the base by an amount in the range of, e.g., 0˜10° or 0˜5°, and the wafer chuck 20, the wafer W, the upper plate 30, the lower plate 40 and the cup 50, which are connected to the base 11, can be accordingly tilted by the same amount.

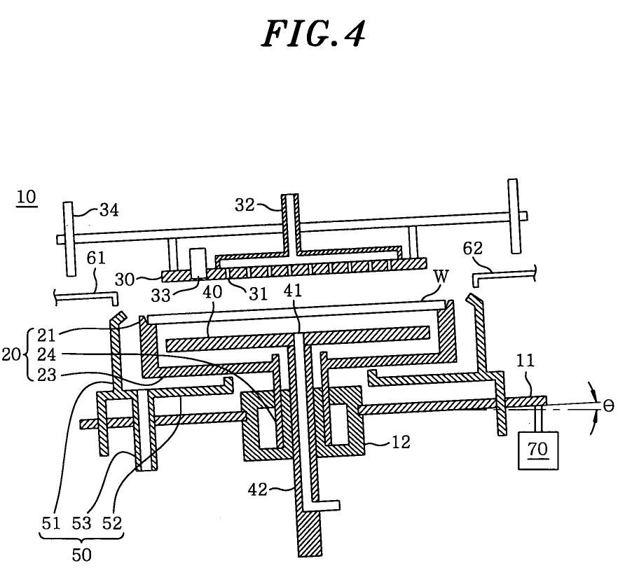

FIG. 4 is a partial cross sectional view showing a state where the wafer W and the like are tilted by the substrate inclining mechanism 70. It can be noted that the base 11 is tilted by the substrate inclining mechanism 70, and the wafer W and the like, which are directly or indirectly connected to the base 11, are tilted by an angle θ.

A solution supply unit 80 is to supply heated processing solutions to the upper plate 30 and the lower plate 40, and includes a temperature controlling mechanism 81, processing solution tanks 82, 83 and 84, pumps P1˜P3, valves V1˜V5 and a mixing box 85. Further, FIG. 3 shows a case of using two kinds of liquid chemicals, e.g., the liquid chemicals 1 and 2. However, the numbers of processing tanks, pumps and valves may be set properly depending on the number of liquid chemicals mixed in the mixing box 85.

The temperature controlling mechanism 81 having therein hot water and the processing solution tanks 82˜84 is a device for heating the processing solutions (pure water and liquid chemicals 1 and 2) in the processing solution tanks 82˜84 by using the hot water; and the processing solutions are appropriately heated, e.g., in the range from the room temperature to about 60° C. For example, a water bath, an immersion heater or an external heater may be employed for adjusting the temperature.

The processing solution tanks 82, 83 and 84 are tanks for accommodating therein the pure water, and the liquid chemicals 1 and 2, respectively.

The processing solutions are drawn out from the processing solution tanks 82˜84 by the pumps P1˜P3. Further, the processing solutions may be pushed out from the processing solution tanks 82˜84 by pressurizing the processing solution tanks 82˜84, respectively.

The lines are opened or closed by the valves V1˜V3 to supply or to stop supplying the processing solutions. Further, valves V4 and V5 are to supply pure water of the room temperature (unheated) to the upper plate 30 and the lower plate 40, respectively.

The mixing box 85 is a vessel for mixing the liquid chemicals 1 and 2 from the processing solution tanks 83 and 84.

The liquid chemicals 1 and 2 are appropriately mixed at a predetermined ratio in the mixing box 85 and the temperatures thereof are adjusted therein to thereby be transferred to the upper plate 30. Further, the pure water can be sent to the lower plate 40 at a controlled temperature.

(Details of the Electroless Plating Processings)

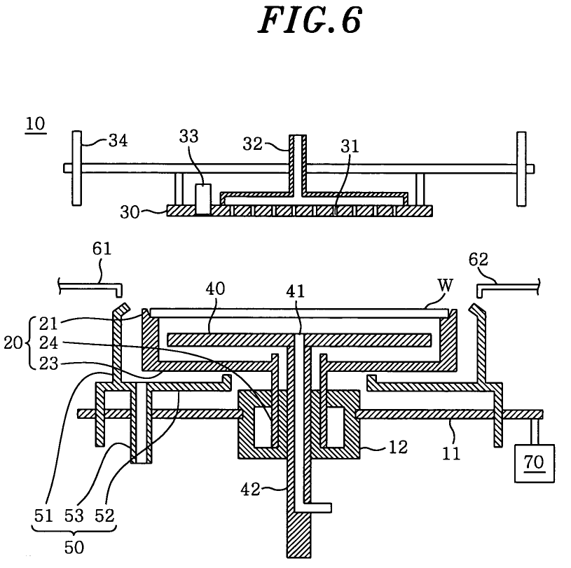

FIG. 5 is a flowchart for showing an exemplary sequence of performing the electroless plating on the wafer W by using the electroless plating apparatus 10 after carrying out the aforementioned steps S11 and S12 on the wafer W. FIGS. 6 through 12 present partial cross sectional views for showing respective statuses of the electroless plating apparatus in case of performing the electroless plating by following the sequence described in FIG. 5. Hereinafter, the sequence will be discussed in detail by using FIGS. 5˜12.

(1) Maintaining the Wafer W (Step S1 and FIG. 6)

The wafer W is maintained on the wafer chuck 20 after executing the aforementioned steps S11 and S12 on the wafer W. For example, the wafer W is mounted on the wafer chuck 20 by a suction arm (substrate transfer mechanism) (not shown), on which the wafer W is adsorbed. Further, the wafer W is maintained and fixed by the wafer supporting claws 21 of the wafer chuck 20. Still further, the cup 50 is lowered down, so that the suction arm can be moved in the horizontal direction below the top surface of the wafer W.

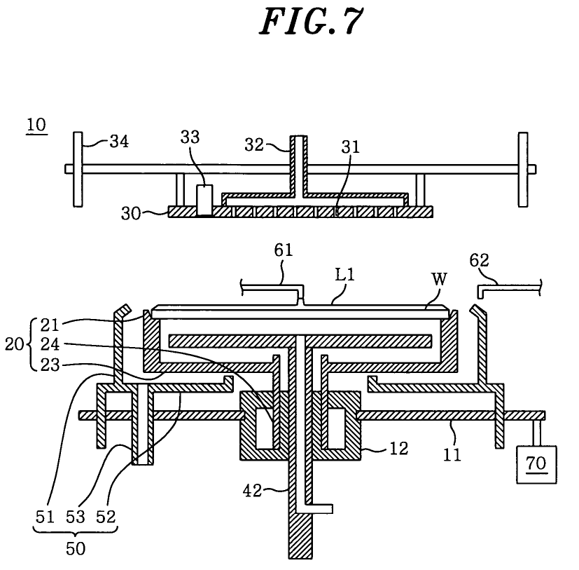

(2) Pre-Treatment of the Wafer W (Step S2 and FIG. 7)

Pre-treatment of the wafer W is performed by rotating the wafer W and supplying the processing solution from the nozzle arm 61 or 62 onto the wafer W.

The wafer W is rotated by rotating the wafer chuck 20 with the hollow motor 12, and the rotation speed may be in the range of, e.g., 100˜200 rpm.

Any one or both of the nozzle arms 61 and 62 are moved above the wafer W to discharge the processing solutions. As for the processing solutions supplied from the nozzle arms 61 and 62, there are sequentially supplied, e.g., pure water for cleaning the wafer W and a liquid chemical for activating the catalyzer of the wafer W, depending on the object of the pre-treatment. At this time, the discharge amount may be, e.g., about 100 mL, enough to form a puddle (layer) of the processing solution on the wafer W. However, the discharge amount may be increased, if necessary. Further, the processing solution to be discharged may be appropriately heated (e.g., in the range from room temperature to about 60° C.).

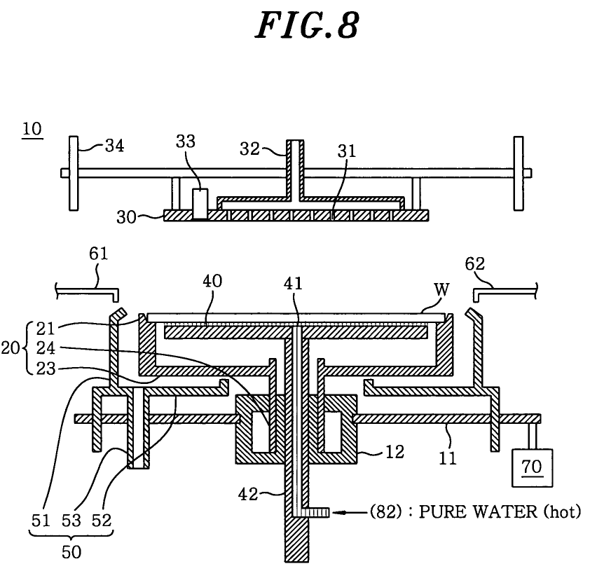

(3) Heating of the Wafer W (Step S3 and FIG. 8)

The wafer W is heated to be kept at an optimum temperature for the reaction of the plating solution.

The lower plate 40 is heated and disposed close to the bottom surface of the wafer W (e.g., a gap between the bottom surface of the wafer W and the upper surface of the lower plate 40: about 0.1˜2 mm); and the pure water heated by the liquid supply unit 80 is supplied through the processing solution injection opening 41. Heated pure water fills the gap between the bottom surface of the wafer W and the upper surface of the lower plate 40 to heat the wafer W.

Further, the water W is heated while it being rotated, so that uniformity in a wafer heating is improved.

By heating the wafer W by using liquid such as pure water or the like, it becomes easy to rotate the wafer W while maintaining the lower plate 40 not to be rotated. Moreover, the bottom surface of the wafer W can be prevented from being contaminated.

The wafer W may be heated by using different heating means. For example, the wafer W may be heated by radiant heat from a heater or lamp. Further, the wafer W may be heated by making a contact with heated lower plate 40.

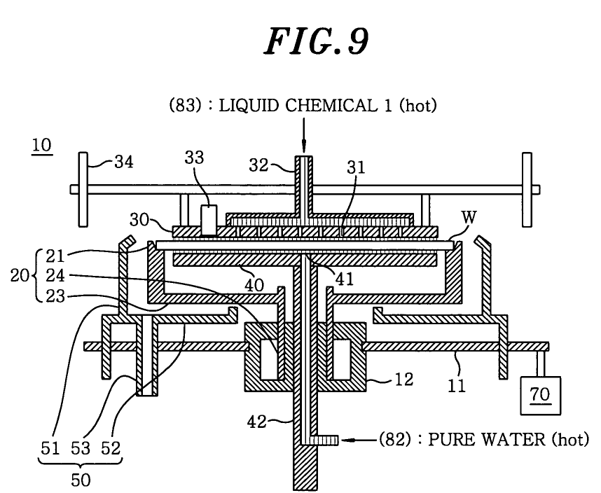

(4) Supplying of the Plating Solution (Step S4 and FIG. 9)

The upper plate 30 is heated and disposed close to the top surface of the wafer W (e.g., a gap between the top surface of the wafer W and the lower surface of the upper plate 30: about 0.1˜2 mm) to supply the liquid chemical for plating (plating solution) through the processing solution injection openings 31 (e.g., 30˜100 mL/min). Supplied plating solution fills the gap between the top surface of the wafer W and the lower surface of the upper plate 30, and then, is drained out to the cup 50. At this time, the temperature of the plating solution is adjusted by the upper plate 30 (e.g., in the range from room temperature to about 60° C.). Further, it is preferable that the temperature of the plating solution to be supplied is adjusted by the liquid supply unit 80.

Here, since the wafer W is rotated by the wafer chuck 20, uniformity in the coating to be formed on the wafer W can be improved. For example, the wafer W is rotated at an angular speed in the range of 10˜50 rpm.

Further, the upper plate 30 may be heated in advance at any step of S1˜S3. By performing the heating of the upper plate 30 in parallel with other processing, the processing time of the wafer W can be reduced.

As described above, the coating is formed on the wafer W by supplying onto the wafer W the plating solution heated at a desired temperature. By rotating the wafer W while the plating solution being supplied thereonto, it is possible to improve the uniformity in the formation of the coating on the wafer W.

In case when the above-described plating solution being supplied, it may be possible to perform following processes:
1) The wafer chuck 20 and the upper plate 30 may be tilted by the substrate inclining mechanism 70, prior to the supply of the plating solution.

Since the wafer W is tilted, a gas staying in a space between the wafer W and the upper plate 30 is rapidly removed, and the space will be refilled with the plating solution. In case where the gas staying in the space between the wafer W and the upper plate 30 is incompletely removed, bubbles will be formed to remain in the space between the wafer W and the upper plate 30, to thereby deteriorate the uniformity in the coating to be formed.

Further, the coating formation by using the plating solution is accompanied with the generation of a gas (e.g., hydrogen), and bubbles are produced due to the resultant gas. Thus, the uniformity in the coating may be deteriorated.

The inclination of the wafer W by the substrate inclining mechanism 70 will reduce the production of the bubbles and facilitate escape of the resultant bubbles, so that the uniformity in the coating can be improved.

2) The temperature of the plating solution may be varied as a function of time.

In this manner, there may change in a structure or a composition of the coating in the thickness direction thereof.

3) The plating solution may be supplied intermittently, not continuously, during the formation of the coating. By efficiently utilizing the plating solution supplied onto the wafer W, it is possible to reduce the amount of the plating solution used.

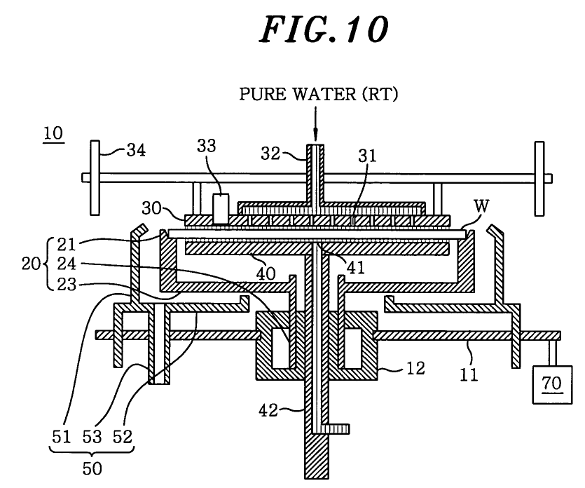

(5) Cleaning of the Wafer W (Step S5 and FIG. 10)

The wafer W is cleaned by using the pure water. The cleaning may be performed by using the pure water as the processing solution to be discharged through the processing solution injection opening 31 of the upper plate 30, instead of the plating solution. At this time, the pure water can be supplied from the processing solution injection opening 41 of the lower plate 40.

In case when cleaning the wafer W, the nozzle arms 61 and 62 may be used. At this time, the supply of the plating solution from the processing solution injection opening 31 of the upper plate 30 is stopped, and then the upper plate 30 is separated from the wafer W. After that, the nozzles 61 and 62 are moved above the wafer W to supply the pure water. In the same manner, it is preferable that the pure water is supplied from the processing solution injection opening 41 of the lower plate 40.

Since the wafer W is cleaned while being rotated, the uniformity in the wafer cleaning can be improved.

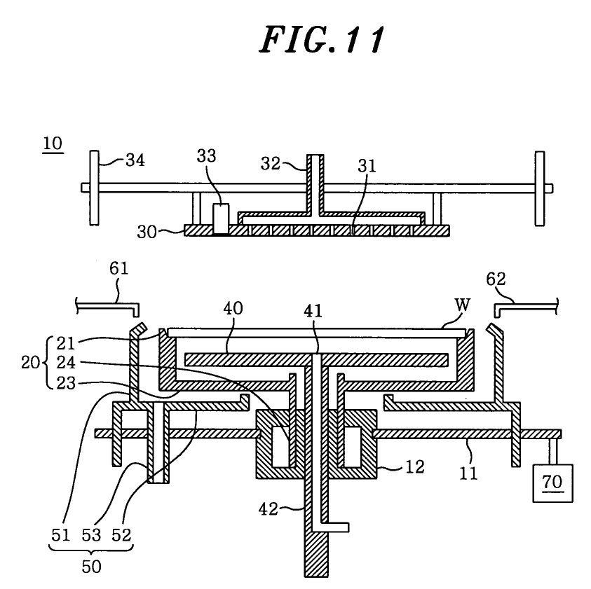

(6) Drying of the Wafer W (Step S6 and FIG. 11)

After the pure water is supplied onto the wafer W, the wafer W is rotated at a high speed to get rid of the pure water thereon. Drying of the wafer W may be facilitated by using the nitrogen gas ejected from the nozzle arms 61 and 62, if necessary.

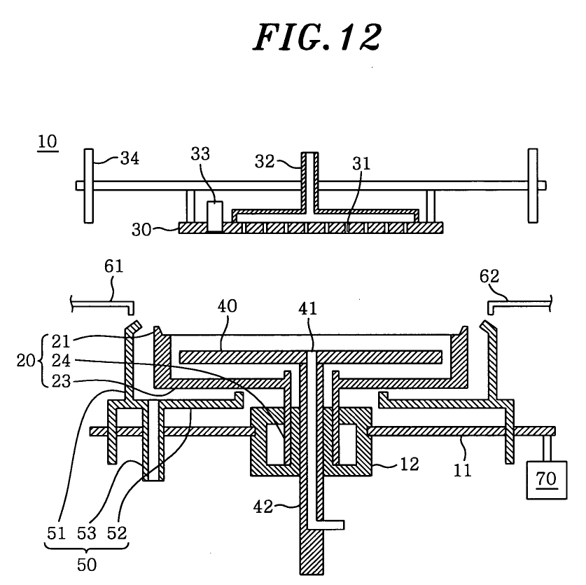

(7) Removing of the Wafer W (Step S7 and FIG. 12)

After the wafer W has been dried, the fixing of the wafer W by the wafer chuck 20 is released. Then, the wafer W is removed from the wafer chuck 20 by the suction arm (substrate transfer mechanism) (not shown).

### Second Embodiment

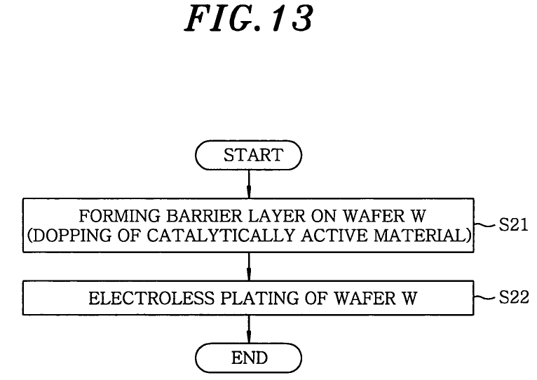

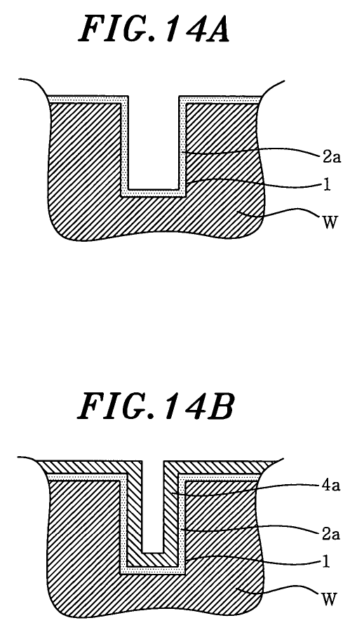

FIG. 13 is a flowchart for showing a sequence of an electroless plating method in accordance with a second embodiment of the present invention. Further, FIGS. 14A and 14B present cross sectional views of the wafer W in respective steps of FIG. 13.

As shown in FIG. 13, in the electroless plating method in accordance with the second embodiment of the present invention, the wafer W is processed in the order of steps S21˜S22. Hereinafter, the processing sequence will be discussed in detail.

(1) Forming a Barrier Layer 2a on the Wafer w (Step S21, FIG. 14A)

The barrier layer 2a is formed on the wafer W. As for the barrier layer 2a, a non-catalytically active material that is not catalytically active on a reducing agent of an electroless plating solution may be used by being mixed (doped) with a catalytically active material that is catalytically active on a reducing agent of an electroless plating solution.

As for the non-catalytically active material, there is used, e.g., any one of Ta, TaN, W, WN, Ti and TiN. By doping the catalytically active material into the non-catalytically active material, the barrier layer 2a can become catalytically activated.

As for the catalytically active material, there may be employed the catalytically active material described in the first embodiment based on the reducing agent of the electroless plating solution.

The barrier layer 2a may be formed by using, e.g., a physical film deposition. Specifically, the barrier layer 2a may be formed by a sputtering method by using a target mixture of the non-catalytically active material and the catalytically active material (or using the respective targets of the non-catalytically active material and the catalytically active material, at the same time). Alternatively, it may be performed by a vacuum deposition (codeposition), wherein the non-catalytically active material and the catalytically active material are simultaneously vaporized.

(2) Electroless Plating of the Wafer W (Step S22, FIG. 14B)

The electroless plating is performed on the wafer W to form an electrolessly plated coating 4a. In this case, since the barrier layer 2a can be catalytically activated based on a doped catalytically active material, the electrolessly plated coating 4a is formed on the barrier layer 2a.

### Third Embodiment

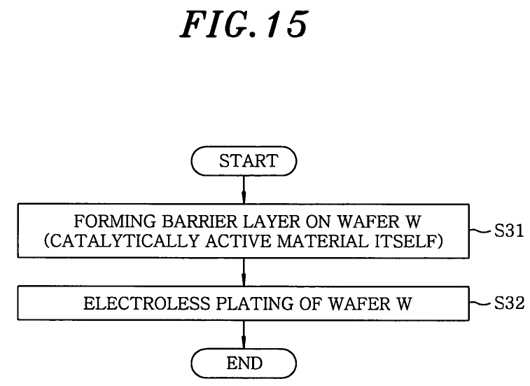

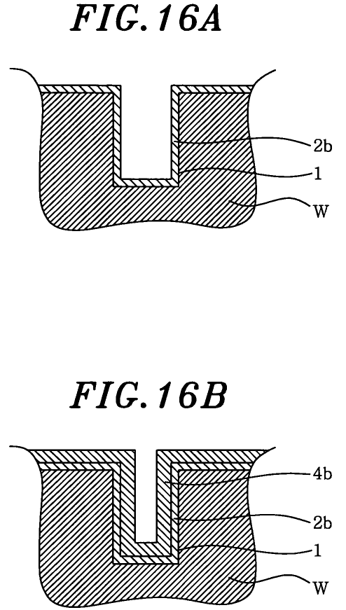

FIG. 15 is a flowchart for showing a sequence of an electroless plating method in accordance with a third embodiment of the present invention. Further, FIGS. 16A and 16B present cross sectional views of the wafer W for respective steps of FIG. 15.

As described in FIG. 15, in the electroless plating method in accordance with the third embodiment of the present invention, the wafer W is processed in the order of steps S31˜S32. Hereinafter, the processing sequence will be discussed in detail.

(1) Forming a Barrier Layer on the Wafer w (Step S31, FIG. 16A)

The barrier layer 2b is formed on the wafer W. The barrier layer 2b is made of a catalytically active material that is catalytically active on a reducing agent of an electroless plating solution.

As for the catalytically active material, there may be employed the catalytically active material described in the first embodiment based on the reducing agent of the electroless plating solution.

The barrier layer 2b may be formed by, e.g., a physical film deposition (e.g., sputtering method or vacuum deposition method) or a chemical film deposition (e.g., CVD method).

(2) Electroless Plating of the Wafer W (Step S32, FIG. 16B)

The electroless plating is performed on the wafer W to form an electrolessly plated coating. In this case, the catalytically active material forming the barrier layer 2b is catalytically active, so that the electrolessly plated coating 4b is formed on the barrier layer 2b.

### EXAMPLE 1

An electrolessly plated coating was formed by following a sequence corresponding to the one given in the third embodiment (wherein the barrier layer is formed by the catalytically active material) by using the electroless plating solution made of copper salt as metal salt and glyoxylic acid as reducing agent.

Specifically, copper electroless platings were performed on respective Ru, Ag, Pt, Ir and Rh bases (barrier layers). Further, as a comparative example, copper electroless platings were performed in case of Cu, TaN, TiN, W, WN and Ta bases.

In case of Ru, Ag, Pt, Ir and Rh bases, adhesivities and deposition rates were good compared with the case of Cu base. Particularly, in case of Ru and Ag bases, adhesivities were good compared with the case of Cu base.

Contrary to this, in case of WN and Ta, deposition of Cu was not performed. Further, in case of TaN, TiN and W bases, formations of Cu were performed. But, adhesivities of formed Cu on the bases were not good.

### EXAMPLE 2

An electrolessly plated coating was formed by following a sequence corresponding to the one given in the third embodiment (the barrier layer is made of the catalytically active material) by using copper salt as metal salt and metal salt (cobalt nitrate) as reducing agent, which form the electroless plating solution.

Specifically, copper electroless platings were performed on respective Ag, Ir and Rh bases (barrier layers) Further, as a comparative example, copper electroless platings were performed in case of Cu, Ta, TaN, TiN, W and WN bases.

In case of Ag, Ir and Rh bases, adhesivities and deposition rates were good compared with the case of Cu base. Particularly, in case of Ag base, adhesivity was better than the case of Cu base.

Contrary to this, in case of Ta, TaN, TiN, W and WN bases, deposition of Cu was not performed.

For example, there may be used as a substrate a glass substrate or the like other than the wafer W.

Further, the electroless plating method in accordance with the present invention may be realized by performing various processes on the barrier layer, and be used in the industrial field.

While the invention has been shown and described with respect to the preferred embodiments, it will be understood by those skilled in the art that various changes and modifications may be made without departing from the spirit and scope of the invention as defined in the following claims.

1. An electroless plating method, comprising:
a diffusion inhibition layer formation step for forming a diffusion inhibition layer for inhibiting a diffusion of a specific material on a substrate by a sputtering or a vacuum deposition, the diffusion inhibition layer being made of a non-catalytically active material that is not catalytically active for an oxidation reaction of a specific reducing agent and a catalytically active material that is catalytically active for an oxidation reaction of the specific reducing agent; and
a coating formation step of forming a coating made of the specific material on the substrate, on which the diffusion inhibition layer has been formed at the diffusion inhibition layer formation step, by using an electroless plating solution containing the specific reducing agent.

2. The electroless plating method of claim 1, wherein the reducing agent is any one of formaldehyde and glyoxylic acid, and the catalytically active material contains at least one of Ir, Pd, Ag, Ru, Rh, Au and Pt.

3. The electroless plating method of claim 1, wherein the reducing agent is hypophosphite, and the catalytically active material contains at least one of Au, Ni, Pd, Ag, Co and Pt.

4. The electroless plating method of claim 1, wherein the reducing agent is metal salt, and the catalytically active material contains at least one of Ag, Rh, Ir, Pd, Au, and Pt.

5. The electroless plating method of claim 1, wherein the reducing agent is dimethylamine borane, and the catalytically active material contains at least one of Ni, Pd, Ag, Au and Pt.

6. An electroless plating method, comprising:
a diffusion inhibition layer formation step for forming a diffusion inhibition layer for inhibiting a diffusion of a specific material on a substrate by a sputtering or a vacuum evaporation, the diffusion inhibition layer being made of a catalytically active material that is catalytically active for an oxidation reaction of a specific reducing agent; and
a coating formation step of forming a coating made of the specific material on the substrate, on which the diffusion inhibition layer has been formed at the diffusion inhibition layer formation step, by using an electroless plating solution containing the specific reducing agent.

7. The electroless plating method of claim 6, wherein the catalytically active material contains at least one of Ir, Pd, Ag, Ru, Rh, Au and Pt, and the reducing agent is any one of formaldehyde and glyoxylic acid.

8. The electroless plating method of claim 6, wherein the catalytically active material contains at least one of Au, Ni, Pd, Ag, Co and Pt, and the reducing agent is hypophosphite.

9. The electroless plating method of claim 6, wherein the catalytically active material contains at least one of Ag, Rh, Ir, Pd, Au, and Pt, and the reducing agent is metal salt.

10. The electroless plating method of claim 6, wherein the catalytically active material contains at least one of Ni, Pd, Ag, Au and Pt, and the reducing agent is dimethylamine borane.

11. The electroless plating method of claim 1, wherein the non-catalytically active material contains at least one of Ta, TaN, W, WN, Ti and TiN.

12. The electroless plating method of claim 6, wherein the catalytically active material contains at least one of Ir, Pd, Ag, Ru, Rh, Au, Pt, Ni and Co.

13. An electroless plating apparatus comprising:
a coating formation unit for forming a coating made of a specific material on a substrate on which a diffusion inhibition layer is formed by a sputtering or a vacuum deposition by using an electroless plating solution containing a specific reducing agent, the diffusion inhibition layer being made of a non-catalytically active material that is not catalytically active for an oxidation reaction of the specific reducing agent and a catalytically active material that is catalytically active for an oxidation reaction of the specified reducing agent, for inhibiting a diffusion of the specific material.

14. The electroless plating apparatus of claim 13, wherein the non-catalytically active material contains at least one of Ta, TaN, W, WN, Ti and TiN.

15. The electroless plating apparatus of claim 13, further comprising a substrate inclining unit for tilting the substrate.

16. An electroless plating apparatus comprising:
a coating formation unit for forming a coating made of a specific material on a substrate, on which a diffusion inhibition layer is formed by a sputtering or a vacuum deposition by using an electroless plating solution containing a specific reducing agent, the diffusion inhibition layer being made of a catalytically active material that is catalytically active for an oxidation reaction of the specific reducing agent, for inhibiting a diffusion of the specific material.

17. The electroless plating apparatus of claim 16, wherein the catalytically active material contains at least one of Ir, Pd, Ag, Ru, Rh, Au, Pt, Ni and Co.

18. The electroless plating apparatus of claim 16, further comprising a substrate inclining unit for tilting the substrate.
